(19) United States
(12) Patent Application Publication
(10) Pub. No.: US 2026/0135370 A1
(43) Pub. Date: May 14, 2026

(54) RECTIFIER SLOT PLUGGABLE CAPACITOR UNIT

(71) Applicant: Vertiv Corporation, Westerville, OH (US)

(72) Inventors: Yahya Sam, Årsta (SE); Hans Thorslund, Tyresö (SE)

(21) Appl. No.: 19/118,556

(22) PCT Filed: Sep. 29, 2023
(86) PCT No.: PCT/US2023/034172

§ 371 Date: Apr. 4, 2025

Related U.S. Application Data
(60) Provisional application No. 63/413,007, filed on Oct. 4, 2022.

(51) Int. Cl. H02H 3/24; H02J 9/06; H02M 1/14; H02M 7/00; H05K 7/14

(52) U.S. Cl. CPC H02H 3/243; H02J 9/061; H02M 1/14; H02M 7/003; H05K 7/1432

(57) ABSTRACT

In some embodiments, apparatuses and methods are provided herein useful to maintaining a minimum supplied voltage and/or current to an equipment. In some embodiments, there is provided a power system including at least one shelf including a plurality of rectifier slots, wherein each rectifier slot is configured to receive a rectifier unit that converts an alternating current (AC) into a direct current (DC); and at least one capacitor unit pluggable and operable in one of the plurality of rectifier slots.

### CROSS-REFERENCE TO RELATED APPLICATION

This application claims priority to U.S. Provisional Application No. 63/413,007, filed Oct. 4, 2022, the entirety of which is incorporated herein by reference in its entirety.

### TECHNICAL FIELD

This invention relates generally to a capacitor unit, and more particularly to a capacitor unit adapted to fit into a rectifier slot.

### BACKGROUND

Generally, a power system supplies power to telecommunications equipment. Such power systems can include components such as high efficiency rectifiers and a control unit as well as other components. Typically, the power system can provide direct current (DC) power of various voltages in order to supply power to cellphone tower site operated by a telecommunications company.

However, the power system may experience a temporary drop in supplied voltage and/or current. The temporary drop in supplied voltage and/or current may cause loss of data transferred across a communication network. Power systems can utilize a battery system to provide a large amount of instantaneous power in order to quickly trigger a circuit breaker. Current battery systems utilize lead acid batteries to provide the large amount of instantaneous power required to compensate for the voltage dip. However, lead acid batteries contain various toxic materials. Moreover, lithium ion type batteries are currently favored to replace lead acid batteries, but are unable to provide the large amount of instantaneous power to compensate for the voltage dip. Accordingly, there is an established need for an alternative system that can provide a large amount of instantaneous power.

### BRIEF DESCRIPTION OF THE DRAWINGS

Disclosed herein are embodiments of systems, apparatuses and methods pertaining to maintaining a minimum supplied voltage and/or current to an equipment. This description includes drawings, wherein:

FIG. 1A illustrates a simplified block diagram of an exemplary power system including a capacitor unit for maintaining a minimum supplied voltage and/or current in accordance with some embodiments;

FIG. 1B illustrates the exemplary power system of FIG. 1A showing current flow during a short circuit in accordance with some embodiments;

FIGS. 2A-2B illustrate a simplified schematic diagram of an exemplary capacitor unit in accordance with some embodiments;

FIGS. 3A-3B illustrate example layouts of capacitors on a PCB board of a capacitor unit in accordance with some embodiments;

FIG. 4 illustrates a simplified illustration of an exemplary power system including capacitor units for maintaining a minimum supplied voltage and/or current in accordance with some embodiments;

FIG. 5 is an exemplary table used by a user to determine the number of capacitor units to configure the power system 100 of FIGS. 1A-1B in accordance with some embodiments;

FIG. 6 is an exemplary capacitor unit in accordance with some embodiments;

FIG. 7 is an exemplary graph illustrating an exemplary effect of capacitor units on an output impedance regulation in accordance with some embodiments;

FIG. 8A shows a flow diagram of an exemplary method of providing power in the power system of FIGS. 1A-1B in accordance with some embodiments; and

FIGS. 8B-8C illustrate simplified illustrations of exemplary power systems where a capacitor unit is pluggable and operable in a rectifier slot in accordance with some embodiments.

Elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein.

### DETAILED DESCRIPTION

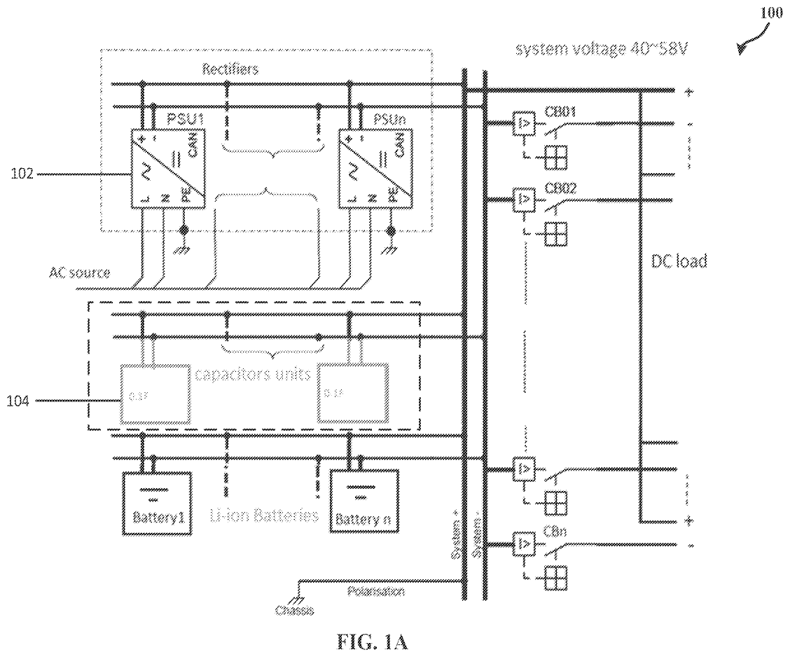

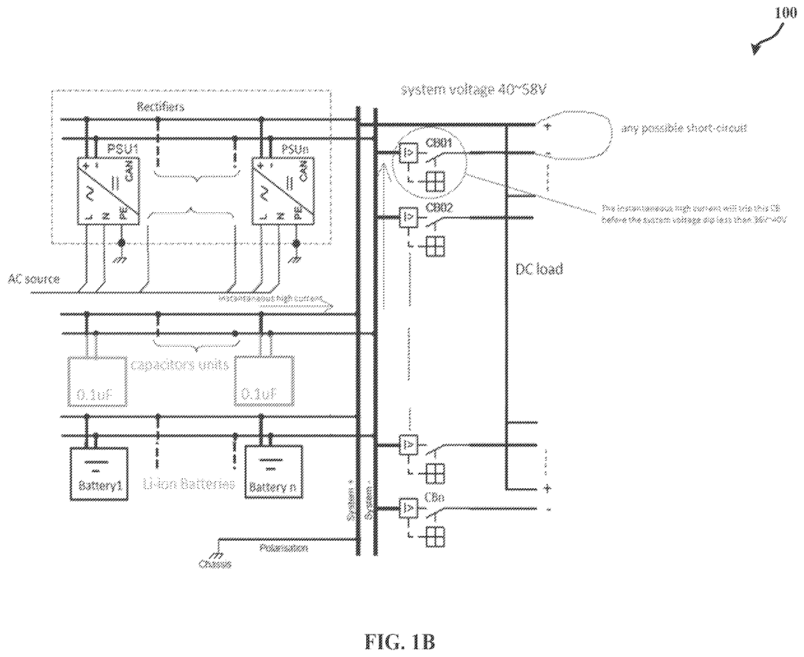

Generally speaking, pursuant to various embodiments, systems, apparatuses and methods are provided herein useful for maintaining a minimum supplied voltage and/or current. Referring initially to FIG. 1-4, a power system includes at least one shelf including a plurality of rectifier slots. Each rectifier slot is configured to receive a rectifier unit that converts an alternating current (AC) into a direct current (DC). The power system includes at least one capacitor unit pluggable and operable in one of the plurality of rectifier slots. In some embodiments, the at least one capacitor unit is adapted to plug into and operate in a rectifier slot adapted to house a rectifier unit in order to avoid any overall system design change of the power system. Avoiding a system design change provides an end user the ability to replace existing rectifier units located in rectifier slots with the at least one capacitor unit. In some embodiments, customers may decide to use lithium ion batteries and/or to remove batteries totally from the facilities or the sites the power system is located.

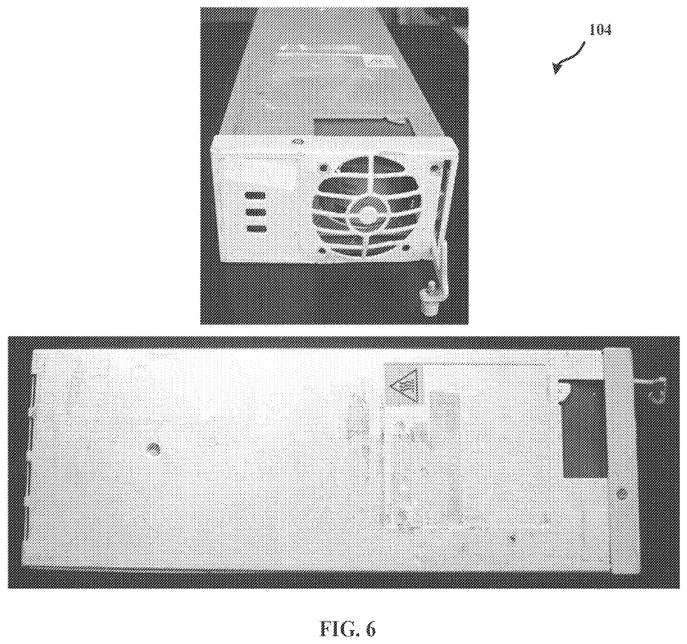

FIG. 1A illustrates a simplified block diagram of an exemplary power system 100 including a capacitor unit 104 for maintaining a minimum supplied voltage and/or current in accordance with some embodiments. FIG. 6 is an exemplary capacitor unit 104 in accordance with some embodiments. In an illustrative non-limiting example, 0.09 F (0.1 F) is shown in FIG. 1A as an exemplary capacitance value of a capacitor in the capacitor unit 104. However, it is understood that other capacitance values (e.g., the same capacitance values and/or mix capacitance values) may be applicable and used based on certain or predetermined capacitance requirements for the board. The power system 100 includes at least one shelf. The at least one shelf includes a plurality of rectifier slots. Each rectifier slot is configured to receive a rectifier unit 102 that converts an alternating current (AC) into a direct current (DC). The power system 100 includes at least one capacitor unit 104 pluggable and operable in one and/or any one of the plurality of rectifier slots. Thus, an existing power system does not have to be modified to accommodate one or more capacitor units. Instead, an existing rectifier slot can be used to plug or receive a capacitor unit 104. Moreover, there is no need to configure or designate a specific slot and/or shelf for receiving a capacitor unit. As such, a benefit of a rectifier slot pluggable capacitor unit is a flexible solution that maintains a minimum supplied voltage and/or current to an equipment without having to modify an existing power system or buy a new one. For example, a capacitor unit 104 may use the same mechanical items, back connector, and/or front item as the rectifier unit 102.

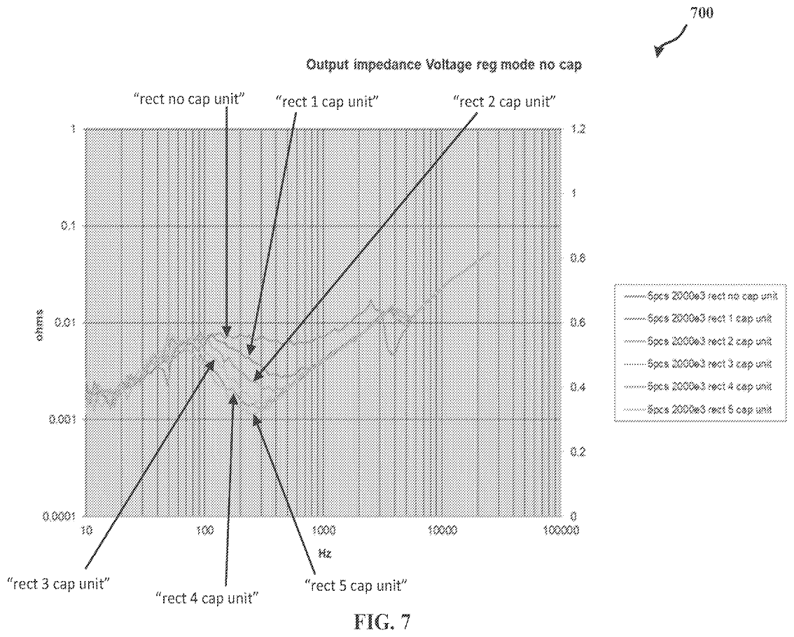

FIG. 1B illustrates the exemplary power system of FIG. 1A showing current flow during a short circuit in accordance with some embodiments. For example, the capacitor unit 104 provides energy to clear the system. In an illustrative non-limiting example, to clear a system, a circuit breaker or fuse maybe opened to isolate the branch having the fault, creating the high current and eventually the drop in system voltage. In another example, the capacitor unit 104 keeps the impedance in the system as low as possible to not get voltage ripple. In an illustrative non-limiting example, FIG. 7 illustrates an exemplary effect of capacitor units on an output impedance regulation.

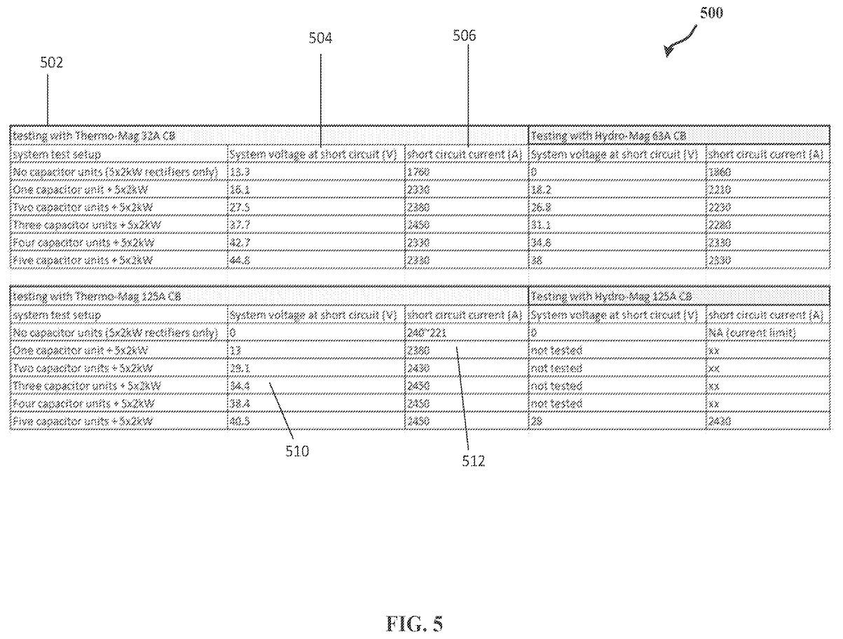

In yet another example, the capacitor unit can supply an immediate and instantaneous amount of energy in order to trip a circuit breaker or fuse in a circuit experiencing an abnormal condition such as a short circuit. For example, exemplary values of capacitor units are shown in FIG. 5. In some embodiments, the amount of energy may be easily calculated based on total capacitance of the capacitor unit and output voltage. As an example, the 0.09 F cap unit may represent a stored energy of 131J at 54V. Thus, one or more of the capacitor units 104 may prevent damage or data loss when a change in load impedance is seen by the power system. For example, immediately tripping a circuit breaker can prevent damage to a system with equipment sensitive to voltage drops. For example, it would be desirable for a system with an abnormal condition that normally operates at 48V to experience an immediate tripping of a circuit breaker before voltage drops below 36V.

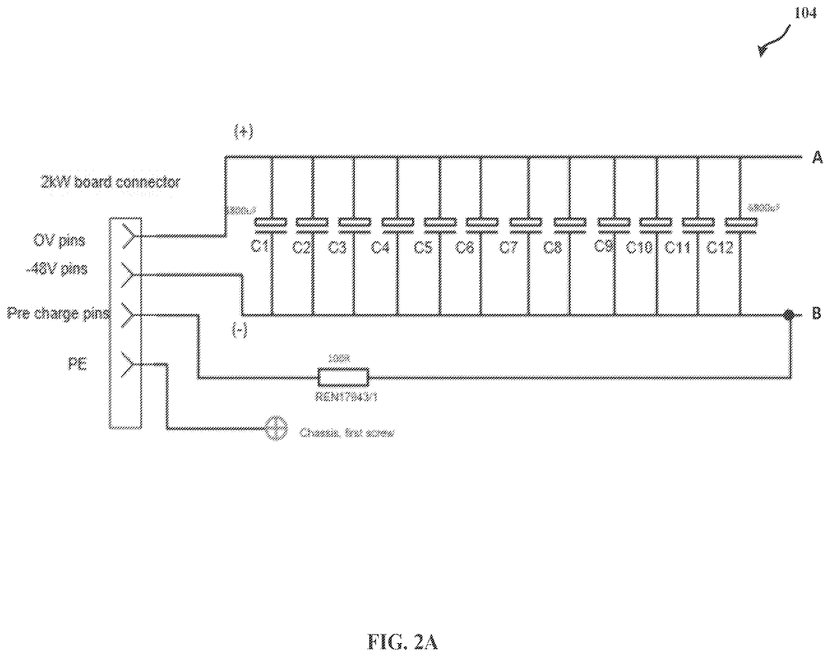

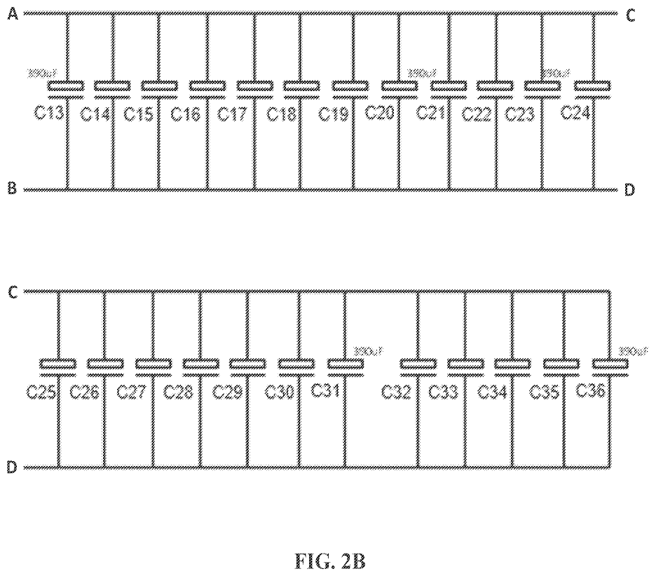

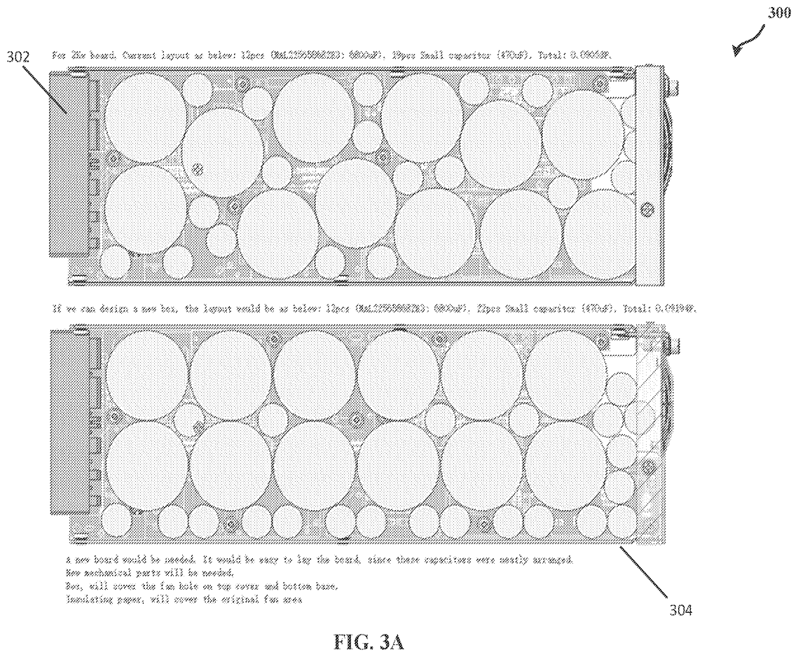

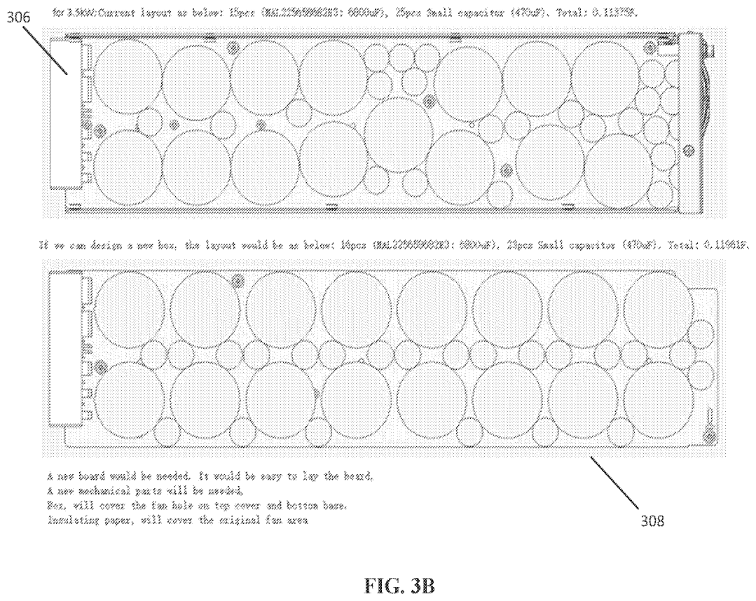

FIGS. 2A-2B illustrate a simplified schematic diagram of an exemplary capacitor unit 104 in accordance with some embodiments. The capacitor unit 104 shown in FIGS. 2A-2B is for illustrative purposes. A capacitor unit 104 may include less than or greater than the number of capacitors shown in FIGS. 2A-2B. In some embodiments, the capacitor unit 104 may include a different, the same, and/or additional capacitance values than shown in FIGS. 2A-2B. In an illustrative non-limiting example, FIGS. 3A-3B illustrate example layouts of capacitors on a printed circuit board (PCB) of a capacitor unit 104 in accordance with some embodiments. For example, a first layout 302 and a second layout 306 illustrate exemplified arrangements of capacitors on an existing rectifier PCB board. In another example, a third layout 304 and a fourth layout 308 illustrate exemplified arrangements of capacitors on a new PCB board. As illustrated in the various layouts depicted in FIGS. 3A-3B, capacitors may be arranged/positioned on a PCB board in a number of ways. In some embodiments, arranging those capacitors that have similar size and/or capacitance value in the same row and/or alternatingly with those different size and/or capacitance value capacitors may allow additional quantity of capacitors to be added onto the PCB board, thereby increasing the total capacitance value output of the capacitor unit 104. For example, the third layout 304 has a total capacitance value 0.09194 F, which is greater than the total capacitance value of 0.09053 F of the first layout 302. Thus, more or less capacitance can be had using the same mechanical form (housing) as existing rectifiers. Moreover, the board dimension of a capacitor unit 104 has the same footprint as a rectifier slot and different physical sizes of capacitors may be chosen to achieve certain or predetermined capacitance requirements for the board. For example, the chosen diameter and/or height of the capacitors are relative to the board dimensions of the capacitor unit 104.

In some embodiments, the capacitor unit 104 may have a similar look and feel on its front as the rectifier unit 102 illustrated in FIGS. 1A-1B. In some embodiments, the capacitor unit 104 may use the same mechanical items, back connector, and/or front item as the rectifier unit 102. In some embodiments, the front or faceplate of the capacitor unit 104 may be made of plastic material. An energy indication, discharge function, and/or light indications may also be located on the front or faceplate of the capacitor unit 104. The capacitor unit 104 may include silicone or rubber protection for the capacitors and/or vibration damper. In some embodiments, the capacitor unit 104 may have an integrated front and floor plate. The capacitors of the capacitor unit 104 may be oriented or mounted vertically and/or horizontally on a PCB board.

In some embodiments, the capacitor unit 104 may be inserted in the power system 100 in two steps. For example, the capacitors in the capacitor unit 104 are charged first or pre-charged via a resistor, then the capacitor unit 104 is inserted totally in its place to avoid any high charging current and to protect the back connector of the capacitor unit 104.

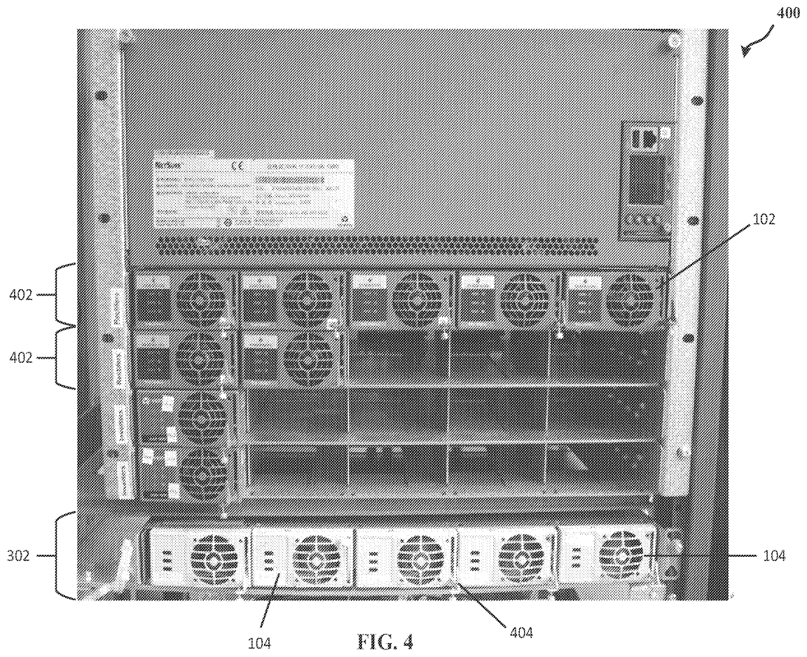

In yet some embodiments, in a pre-charge capacitors of the capacitor unit 104, the capacitor unit 104 may be configured or secured in the “arm” solution 404 that prevents a user from accidentally removing the capacitor unit 104 from a slot as shown in FIG. 4. In some embodiments, there may be fasteners, such as screws and/or thumbscrews, which may be removed by a user before the user can remove the capacitor unit 104 from the slot.

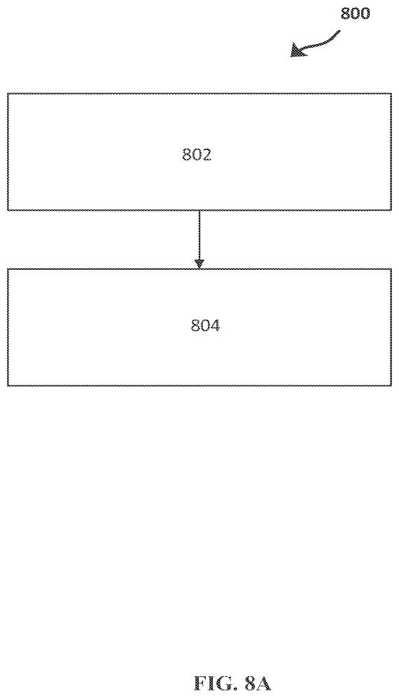

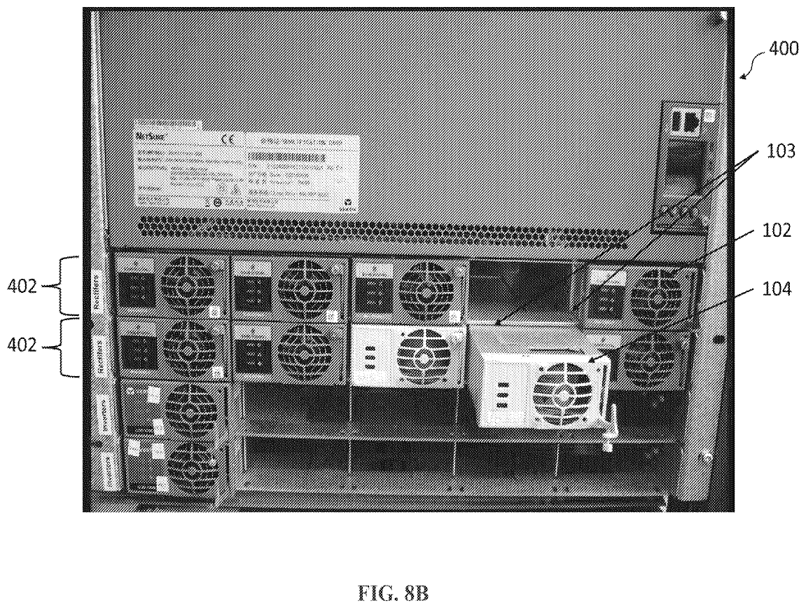

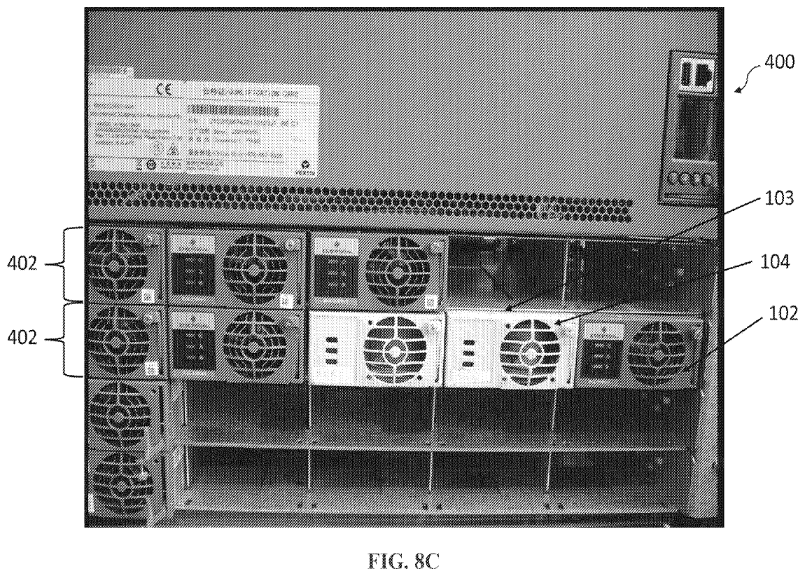

FIG. 4 illustrates a simplified illustration of an exemplary power system 100 of FIGS. 1A-1B in accordance with some embodiments. The power system 100 includes a rack 400 including a plurality of shelves 402. Rack 400 can be a 19 inch (48.26 cm) EIA compliant rack cabinet system (also known as a server rack). Moreover, each shelf 402 can have an overall height of about 1.75 inches (44.5 mm) which corresponds to the dimensions of a single “U” space in rack 400. Three of the plurality of shelves are rectifier shelves 402 with one of the rectifier shelves being populated with five capacitor units 104 instead of the rectifier units 102. In some embodiments, a mix of rectifier units 102 and capacitor units 104 may be configured for each rectifier shelf, as illustrated in FIGS. 8B-8C. A housing of the capacitor unit 104 may be similar to the housing of the rectifier unit 102. In such an embodiment, one or more coupling connectors may be the same.

In some embodiments, as shown in FIG. 5, a user may configure the number of capacitor units 104 in the power system 100 based on a table 500. The table 500 may include a predefined association of a number of capacitor units 104 to at least one of a voltage threshold 504 at short circuit or a current threshold 506 at a short circuit. By one approach, the voltage threshold 504 and/or the current threshold 506 are minimum voltage and/or minimum current that the power system 100 maintains despite a short circuit and/or a change in load impedance seen by the power system 100. The predefined association may be based on one or more of a type of circuit breaker 502 or fuse coupled to the power system 100, and a load ripple experienced by the power system 100. As such, the user may customize the power system 100 based on the equipment serviced by the power system 100 and/or environmental factors the power system 100 is subjected to. For example, a power system 100 including a first circuit breaker 508 is required to keep a minimum voltage of 34.4 during a short circuit 510. In such an example, based on the table 500, three capacitor units 104 are to be installed in three empty rectifier slots in order for the power system 100 to keep the voltage supply at a minimum of 34.4 volts.

Continuing the illustrative non-limiting example above, based on the table 500, a single capacitor unit 104 is required to maintain a minimum amperage of 2380 during a short circuit 512. The single capacitor unit 104 may be installed in an empty or available rectifier slot in order for the power system 100 to keep a minimum current supply of 2380 amps. For example, in FIG. 5, five (5) rectifiers are installed in the power system and a capacitor unit 104 can be added one by one to determine how low (dip) the system voltage will be at any short-circuit based on the type of the circuit breaker (CB), the rating of the CB and/or the quantity of the capacitors units 104 in the system.

FIG. 8A shows a flow diagram of an exemplary method 800 of providing power in the power system 100 of FIGS. 1A-1B in accordance with some embodiments. In some embodiments, the method 800 includes, at step 802, providing at least one shelf comprising a plurality of rectifier slots, wherein each rectifier slot is configured to receive a rectifier unit that converts an alternating current (AC) into a direct current (DC). This is illustrated in FIG. 8B, which shows a rack 400 including a plurality of shelves 402 having rectifier slots 103 configured to receive a rectifier unit 102. Alternatively, or in addition to, the method 800 may include, at step 804, providing at least one capacitor unit pluggable and operable in one of the plurality of rectifier slots. This is illustrated in FIG. 8C, which shows the capacitor unit 104 pluggable and operable in rectifier slot 103. FIG. 8C also shows a mix of rectifier units 102 and capacitor units 104 arranged in the same row/on the same shelf.

In some embodiments, the method 800 may include providing, by the at least one capacitor unit, at least one of a supplied voltage or current sufficient to maintain operational status of a load coupled to the power system. In some embodiments, the method 800 may include at least one of: providing, by the at least one capacitor unit, energy to clear the power system; keeping, by the at least one capacitor unit, impedance of the power system to a threshold value to avoid voltage ripple; or supplying, by the at least one capacitor unit, a threshold current to trip a circuit breaker.

Those skilled in the art will recognize that a wide variety of other modifications, alterations, and combinations can also be made with respect to the above-described embodiments without departing from the scope of the invention, and that such modifications, alterations, and combinations are to be viewed as being within the ambit of the inventive concept.

What is claimed is:

1. A power system comprising:
at least one shelf comprising a plurality of rectifier slots, wherein each rectifier slot is configured to receive a rectifier unit that converts an alternating current (AC) into a direct current (DC); and
at least one capacitor unit pluggable and operable in one of the plurality of rectifier slots.

2. The power system of claim 1, wherein the at least one capacitor unit is configured to provide at least one of a supplied voltage or current sufficient to maintain operational status of a load coupled to the power system.

3. The power system of claim 1, wherein the at least one capacitor unit comprises a plurality of capacitors, and wherein each capacitor has the same capacitance value.

4. The power system of claim 1, wherein the at least one capacitor unit comprises a plurality of capacitors, and wherein at least two of the plurality of capacitors have a different capacitance value relative to one another.

5. The power system of claim 1, wherein the at least one capacitor unit comprises a housing and a back connector, wherein the housing and the back connector have the same dimensions as a housing and a back connector of the rectifier unit.

6. The power system of claim 1, wherein the at least one capacitor unit is configured to at least one of:
provide energy to clear the power system;
keep impedance of the power system to a threshold value to avoid voltage ripple; or
supply a threshold current to trip a circuit breaker.

7. The power system of claim 1, wherein the at least one capacitor unit comprises a plurality of capacitors, wherein capacitors having the same capacitance value are arranged in the same row.

8. The power system of claim 1, wherein the at least one capacitor unit comprises a plurality of capacitors, and wherein each capacitor in a row is positioned adjacent to another capacitor having a different capacitance value.

9. The power system of claim 1, wherein the at least one capacitor unit is pre-charged prior to installing in the one of the plurality of rectifier slots.

10. The power system of claim 1, wherein the at least one capacitor unit is secured in the one of the plurality of rectifier slots to prevent an accidental removal from the one of the plurality of rectifier slots.

11. A method for providing power in a power system, the method comprising:
providing at least one shelf comprising a plurality of rectifier slots, wherein each rectifier slot is configured to receive a rectifier unit that converts an alternating current (AC) into a direct current (DC); and
providing at least one capacitor unit pluggable and operable in one of the plurality of rectifier slots.

12. The method of claim 11, further comprising providing, by the at least one capacitor unit, at least one of a supplied voltage or current sufficient to maintain operational status of a load coupled to the power system.

13. The method of claim 11, wherein the at least one capacitor unit comprises a plurality of capacitors, and wherein each capacitor has the same capacitance value.

14. The method of claim 11, wherein the at least one capacitor unit comprises a plurality of capacitors, and wherein at least two of the plurality of capacitors have a different capacitance value relative to one another.

15. The method of claim 11, wherein the at least one capacitor unit comprises a housing and a back connector, wherein the housing and the back connector have the same dimensions as a housing and a back connector of the rectifier unit.

16. The method of claim 11, further comprising at least one of:
providing, by the at least one capacitor unit, energy to clear the power system;
keeping, by the at least one capacitor unit, impedance of the power system to a threshold value to avoid voltage ripple; or
supplying, by the at least one capacitor unit, a threshold current to trip a circuit breaker.

17. The method of claim 11, wherein the at least one capacitor unit comprises a plurality of capacitors, wherein capacitors having the same capacitance value are arranged in the same row.

18. The method of claim 11, wherein the at least one capacitor unit comprises a plurality of capacitors, and wherein each capacitor in a row is positioned adjacent to another capacitor having a different capacitance value.

19. The method of claim 11, wherein the at least one capacitor unit is pre-charged prior to installing in the one of the plurality of rectifier slots.

20. The method of claim 11, wherein the at least one capacitor unit is secured in the one of the plurality of rectifier slots to prevent an accidental removal from the one of the plurality of rectifier slots.
